(19) United States
(12) Patent Application Publication
(10) Pub. No.: US 2025/0258977 A1
(43) Pub. Date: Aug. 14, 2025

(54) FINITE ELEMENT MODELING SYSTEMS AND METHODS FOR HYDRAULIC FRACTRURING PROBLEMS BASED ON LARGE LANGUAGE MODEL

(71) Applicant: ZHEJIANG UNIVERSITY, Hangzhou (CN)

(72) Inventors: Fushen LIU, Hangzhou (CN); Mingwei SU, Hangzhou (CN)

(73) Assignee: ZHEJIANG UNIVERSITY, Hangzhou (CN)

(21) Appl. No.: 19/096,724

(22) Filed: Apr. 1, 2025

(30) Foreign Application Priority Data
Dec. 3, 2024 (CN) 202411770349.3

(51) Int. Cl. G06F 30/23

(52) U.S. Cl. CPC G06F 30/23

(57) ABSTRACT

Disclosed is a finite element modeling system and method for hydraulic fracturing problems based on a large language model. The method is implemented by the system. The method comprises: a user inputting a key description of a finite element model desired to be generated; a large language model of a cloud service platform generating a key parameter file; a mesh tool generating a mesh file; a parameter mesh coupling tool generating a finite element model file; a computing server executing the finite element model file, a system output unit prompting the user of completion of modeling and execution, and a display interface displaying a visualized finite element model and an execution result; the user determining whether an expectation is satisfied; if the expectation is not satisfied, the user re-inputting the description; if the expectation is satisfied, the user outputting the finite element model and the execution result.

### CROSS-REFERENCE TO RELATED APPLICATIONS

This application claims priority to Chinese Application No. 202411770349.3, filed on Dec. 3, 2024, the entire contents of which are incorporated herein by reference.

### TECHNICAL FIELD

The present disclosure relates to the field of numerical simulation, and in particular to a finite element modeling system and method for hydraulic fracturing problems based on a large language model.

### BACKGROUND

Accurate simulation for complex physical phenomena of hydraulic fracturing problems can be implemented based on finite element analysis to depict a dynamic process of rock and fluid interaction during a fracturing process, including fracture formation, propagation, stress distribution, etc. By creating high-resolution 2D and 3D hydraulic fracturing finite element models, the fracturing design be optimized, the oil and gas recovery rate can be improved, field measurement data can be integrated to enhance the reliability and accuracy of the models, and a scientific basis for decision making can be provided based on visualization of the models. However, the application of the finite element analysis in automated generation of the finite element models is insufficient. In practical engineering application, the quality and the computational stability of an automatically generated finite element model often fail to fulfil the accuracy requirements of the engineering, and still require manually repeated adjustment and optimization by professionals, which extends the modeling time and limits the adaptability and application scope in a wider range of complex engineering scenarios.

Therefore, it is desirable to provide a finite element modeling system and method for hydraulic fracturing problems based on a large language model, which can quickly and accurately carry out finite element modelling and provide a scientific basis for decision making in the engineering.

### SUMMARY

One or more embodiments of the present disclosure provide a finite element modeling system for hydraulic fracturing problems based on a large language model. The finite element modeling system may include a client, a cloud service platform, and a computing server. The client may consist of an interactive interface and a display interface. The interactive interface may include a user input unit and a system output unit. The display interface may serve as a window of the system for displaying a visualized finite element model and an execution result. The cloud service platform may include a storage space, a first input terminal, a second input terminal, a third input terminal, a transmission terminal, a trained large language model, a mesh tool, and a parameter mesh coupling tool. The first input terminal may be an input port configured to receive an external data input and a user input and input the external data input and the user input to the large language model. The second input terminal may be an input port configured to receive a key parameter file and input the key parameter file to the mesh tool. The third input terminal may be an input port configured to receive the key parameter file and a mesh file and input the key parameter file and the mesh file to the parameter mesh coupling tool. The transmission terminal may be a transmission terminal port configured to transmit a finite element model file from the storage space of the cloud service platform to a storage unit of the computing server. The trained large language model may be a large language model configured to generate the key parameter file based on a user input content. The mesh tool may be a tool configured to generate the mesh file based on the key parameter file being invoked by the cloud service platform. The parameter mesh coupling tool may be a tool configured to generate the finite element model file based on the key parameter file and the mesh file being invoked by the cloud service platform. The computing server may include the storage unit, an operation unit, and a visualization unit.

One of the embodiments of the present disclosure provides a finite element modeling method for hydraulic fracturing problems based on a large language model. The finite element modeling method may include: a user inputting a key description of a finite element model desired to be generated into a user input unit, an API interface being consistent with an API interface of a trained large language model; the large language model of a cloud service platform generating a key parameter file by processing the description input by the user; a mesh tool generating a mesh file by reading the key parameter file; and a parameter mesh coupling tool generating a finite element model file by processing the key parameter file and the mesh file; a computing server executing the finite element model file, the finite element model and an execution result being presented using a visualization unit, a system output unit prompting the user of completion of modeling and execution, and a display interface displaying a visualized finite element model and the execution result; the user determining whether an expectation is satisfied; in response to determining that the user expectation is not satisfied, the user needing to re-input the description; in response to determining that the user expectation is satisfied, the user being capable of choosing to output the finite element model and the execution result.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering indicates the same structure, wherein:

FIG. 1 is a block diagram illustrating a finite element modeling system for hydraulic fracturing problems based on a large language model and a plurality of files according to some embodiments of the present disclosure;

FIG. 2 is a flowchart illustrating an exemplary process of training a large language model according to some embodiments of the present disclosure;

FIG. 3 is a flowchart illustrating an exemplary process of training a parameter mesh coupling tool according to some embodiments of the present disclosure;

FIG. 4 is a flowchart illustrating an exemplary process from a user input content to displaying a finite element model and an execution result according to some embodiments of the present disclosure;

FIG. 5 is a block diagram illustrating an exemplary finite element modeling system for hydraulic fracturing problems based on a large language model according to some embodiments of the present disclosure;

FIG. 6 is a block diagram illustrating categorization of sub-problems of hydraulic fracturing problems according to some embodiments of the present disclosure;

FIG. 7 is a flowchart illustrating an exemplary process of training a large language model according to some embodiments of the present disclosure;

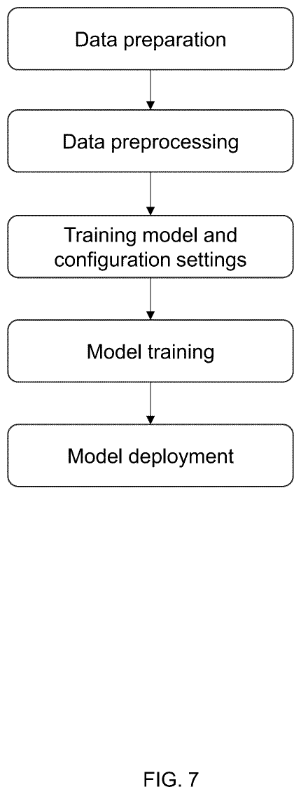

FIG. 8 is a schematic diagram illustrating a key parameter file according to some embodiments of the present disclosure; and

FIG. 9 is a flowchart illustrating an exemplary process of a user modeling by using a finite element modeling system for hydraulic fracturing problems based on a large language model according to some embodiments of the present disclosure.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system,” “device,” “unit” and/or “module” used herein are a way to distinguish between different components, elements, parts, sections, or assemblies at different levels. However, the terms may be replaced by other expressions if other words accomplish the same purpose.

As shown in the present disclosure and in the claims, unless the context clearly suggests an exception, the words “one,” “a,” “an,” “one kind,” and/or “the” do not refer specifically to the singular, but may also include the plural. Generally, the terms “including” and “comprising” suggest only the inclusion of clearly identified steps and elements, however, the steps and elements that do not constitute an exclusive list, and the method or apparatus may also include other steps or elements.

The current intelligence level of automated generation of a finite element model for hydraulic fracturing is limited, which is difficult to effectively replace human professional determination. Finite element modeling involves a complex geometric processing, mesh delineation, material property setting, boundary condition definition, etc., which requires in-depth professional knowledge and extensive practical experience, and is usually difficult to complete automatically by intelligent means. In addition, the quality and the computational stability of an automatically generated model often fail to fulfil the accuracy requirements of the engineering, and still require manual adjustment and optimization by professionals. Accordingly, the automated generation of the finite element model still has great challenges in terms of the degree of intelligence and accuracy guarantee.

A large language model has the ability to implement incremental learning by continuously improving the modeling effect by gradually updating data and knowledge to adapt to the dynamically changing needs. Meanwhile, the large language model demonstrates a strong ability in data understanding and generation in automated modeling, which facilitates to automate complex modeling processes and significantly reduce human intervention. In addition, the large language model has a high computational efficiency, and can quickly generate a required model with reasonable resource allocation, thereby significantly reducing the time cost. Accordingly, automated modeling based on the large language model plays an important role in improving the modeling efficiency and accuracy.

Therefore, some embodiments of the present disclosure provide a finite element modeling system and method for hydraulic fracturing problems based on a large language model, which performs automated modeling through a large language model and solves the problems such as low modeling efficiency and poor modeling accuracy, thereby providing a scientific basis for engineering decision.

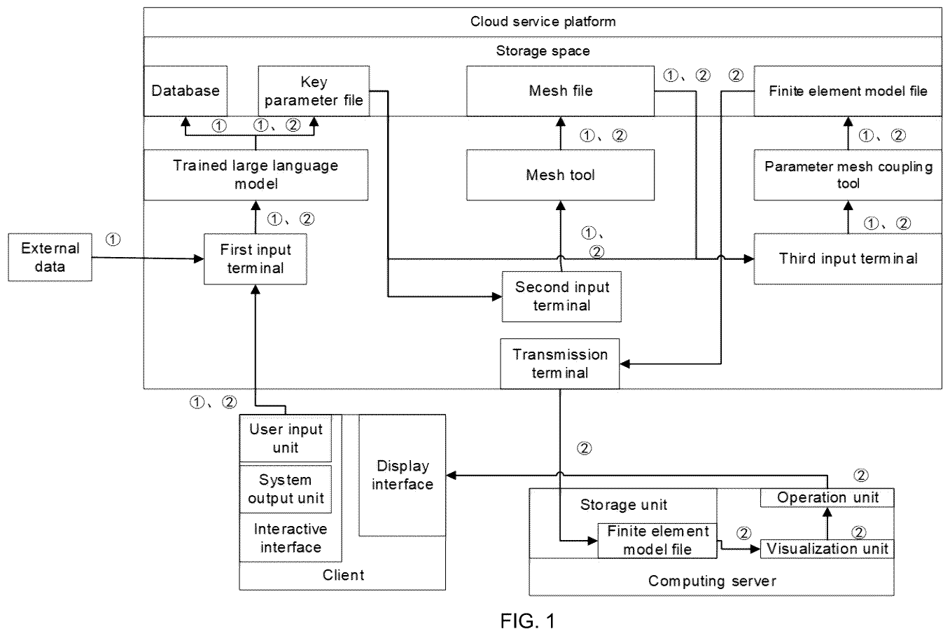

FIG. 1 is a block diagram illustrating a finite element modeling system for hydraulic fracturing problems based on a large language model and a plurality of files according to some embodiments of the present disclosure.

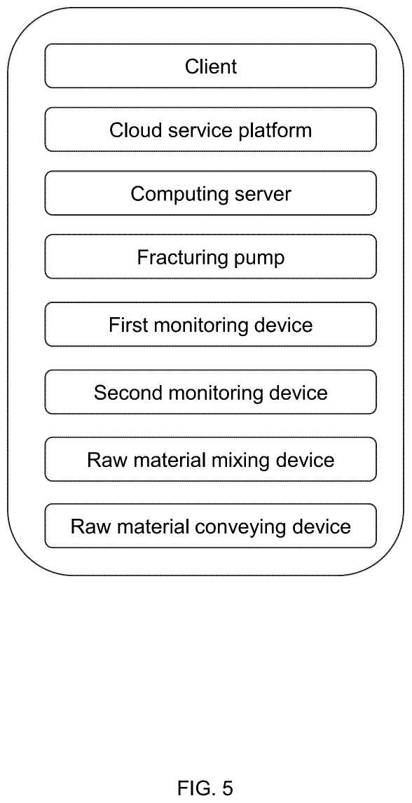

Some embodiments of the present disclosure provide a finite element modeling system (hereinafter referred to as the “system”) for hydraulic fracturing problems based on a large language model. As shown in FIG. 1 and FIG. 5, the system may include a client, a cloud service platform, and a computing server.

The client refers to a terminal device or an application through which a user interacts with the system. In some embodiments, the client may consist of an interactive interface and a display interface.

The interactive interface refers to an interface where the user interacts with the system. The interactive interface may include a user input unit and a system output unit.

The user input unit is a window where the user inputs a content in a composite form of texts, pictures, and vector graphics. The system output unit is a window where the system displays a prompt to the user.

The display interface may serve as a window of the system for displaying a visualized finite element model and an execution result.

The cloud service platform refers to a service platform based on a cloud computing technology. In some embodiments, the cloud service platform may include a storage space, a first input terminal, a second input terminal, a third input terminal, a transmission terminal, a trained large language model, a mesh tool, and a parameter mesh coupling tool.

In some embodiments, the storage space is a space configured to store a database and a key parameter file generated by the trained large language model, a mesh file generated by the mesh tool, and a finite element model file generated by the parameter mesh coupling tool.

In some embodiments, the database may be configured to store all data occurring during a training process of the large language model in the form of “keyword-data value”. The key parameter file is a result generated by the trained large language model processing the user input content, a parameter file in the key parameter file being in the form of “keyword-data value”. The mesh file may be generated by the cloud service platform invoking the mesh tool based on the key parameter file. The finite element model file may be generated by the parameter mesh coupling tool coupling the key parameter file with the mesh file, the finite element model file being capable of being executed directly by the operation unit to generate a result.

The user input content refers to a content input by the user after the large language model is trained, and may include a content that the user needs to be extracted by the trained large language model.

It is understood that the data stored in the database facilitates subsequent processing of the user input content by the trained large language model to generate the key parameter file.

The first input terminal is an input port configured to receive an external data input and a user input and input the external data input and the user input to the large language model. The second input terminal is an input port configured to receive the key parameter file and input the key parameter file to the mesh tool. The third input terminal is an input port configured to receive the key parameter file and the mesh file and input the key parameter file and the mesh file to the parameter mesh coupling tool.

The transmission terminal is a transmission port configured to transmit the finite element model file from the storage space of the cloud service platform to a storage unit of the computing server. The trained large language model is a large language model configured to generate the key parameter file based on the user input content. The mesh tool is a tool configured to generate the mesh file based on the key parameter file being invoked by the cloud service platform. For example, the mesh tool may include one or more of Adobe Illustrator, Blender, etc. The parameter mesh coupling tool may be a tool configured to generate the finite element model file based on the key parameter file and the mesh file being invoked by the cloud service platform. For example, the parameter coupling tool may include one or more of ANSYS, COMSOL, etc.

In some embodiments, the computing server may include a storage unit, an operation unit, and a visualization unit.

In some embodiments, the storage unit may be a unit configured to store the finite element model file. The finite element model file in the storage unit may be transmitted from the storage space through the transmission terminal of the cloud service platform. The operation unit may be a unit configured to execute the finite element model file. The visualization unit may be a unit configured to visualize the finite element model and the execution result.

As shown in FIG. 1, some embodiments of the present disclosure provide the finite element modeling system for hydraulic fracturing problems based on the large language model. The system may include two-step implementation routes, i.e., a first implementation route and a second implementation route whose corresponding serial numbers are denoted as \textcircled{1} and \textcircled{2}, respectively.

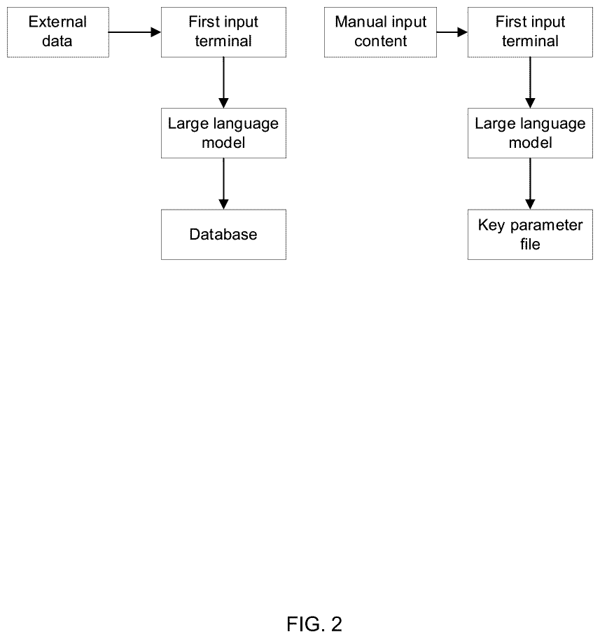

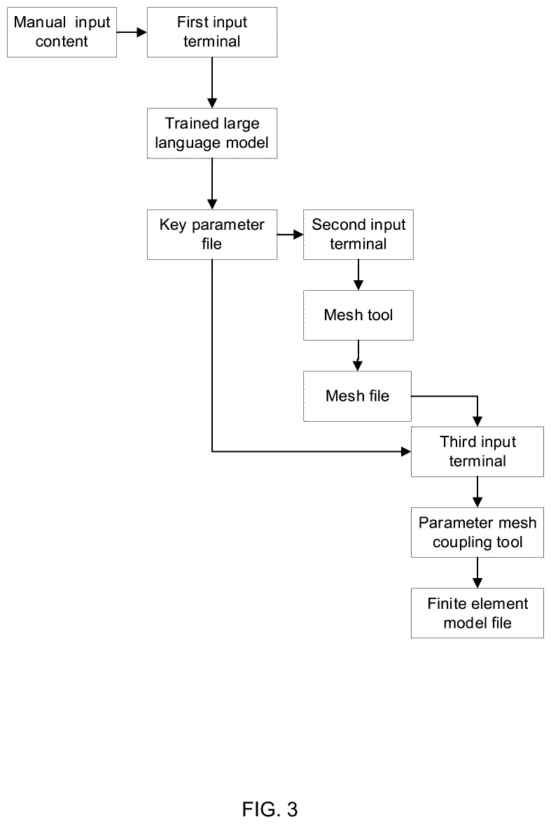

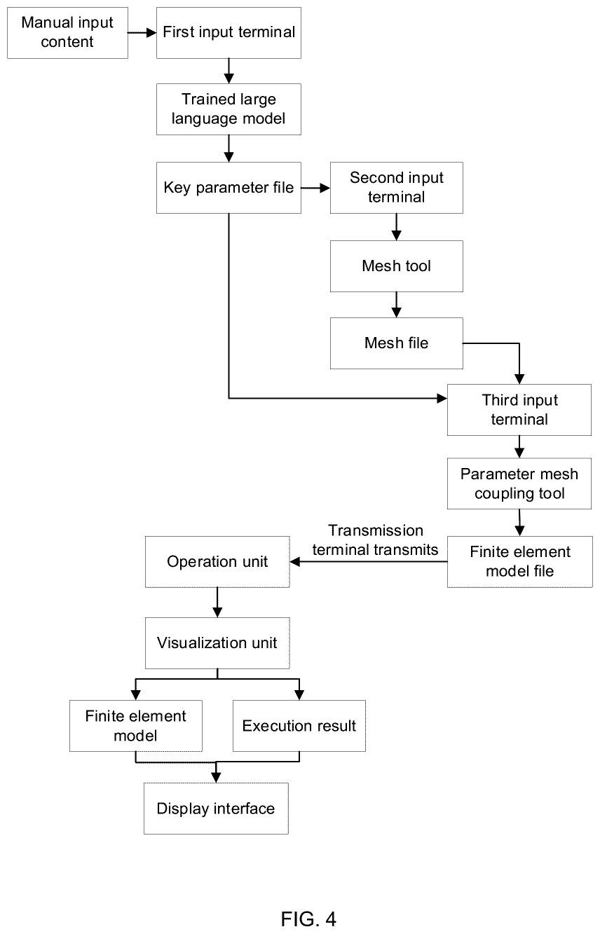

FIG. 2 is a flowchart illustrating an exemplary process of training a large language model according to some embodiments of the present disclosure. FIG. 3 is a flowchart illustrating an exemplary process of training a parameter mesh coupling tool according to some embodiments of the present disclosure. FIG. 4 is a flowchart illustrating an exemplary process from a user input content to displaying a finite element model and an execution result according to some embodiments of the present disclosure.

In some embodiments, the first implementation route may include: training the large language model built in the system, a training process being performed on a cloud service platform. As shown in FIG. 2, a large plurality of external data and manual input contents are first input into the large language model as an input content through a first input terminal to train the large language model. In the training process, the main goal is to generate a database and a key parameter file in the form of “keyword-data value”. As shown in FIG. 3, a mesh tool is invoked by the cloud service platform to generate a mesh file based on the key parameter file generated by a trained large language model, and the parameter mesh coupling tool is invoked by the cloud service platform to generate a finite element model file capable of executing in an operation unit based on the key parameter file and the mesh file.

The manual input content refers to a content manually input during the training process of the large language model, which may include at least one of manual categorization and annotation of the external data, feedback or correction of the result generated by the large language model, etc.

In some embodiments, the second implementation route may include: a process from the user inputting content to the computing server to the display interface displaying the finite element model and the execution result. As shown in FIG. 4, a first input terminal receives a content input by a user in a user input unit, and a trained large language model generates a key parameter file; a second input terminal receives the key parameter file, and a mesh tool generates a mesh file; a third input terminal receives the key parameter file and the mesh file, and a parameter mesh coupling tool generates a finite element model file; the finite element model file is transmitted to a storage unit of a computing server by a transmission terminal; an operation unit executes the finite element model file, and a visualization unit processes the finite element model and an execution result, and displays the finite element model and the execution result to the user in a display interface.

In some embodiments of the present disclosure, with application of the finite element modeling system for the hydraulic fracturing problems based on the large language model, the key parameter file can be generated based on the user input, and the finite element model file can be generated based on the key parameter file and the mesh file, the finite element model file allowing continuous interaction between the user and the system until a desired finite element model is obtained, thereby realizing efficient acquisition of the finite element model.

It should be noted that the above descriptions of the finite element modeling system for the hydraulic fracturing problems based on the large language model and the modules thereof are provided only for descriptive convenience, and do not limit the present disclosure to the scope of the cited embodiments. It is understood that for those skilled in the art, after understanding the principle of the system, it is possible to arbitrarily combine the modules or form a sub-system to be connected to other modules without departing from this principle.

FIG. 5 is a block diagram illustrating an exemplary finite element modeling system for hydraulic fracturing problems based on a large language model according to some embodiments of the present disclosure. As shown in FIG. 5, the system may include a fracturing pump. In some embodiments, a computing server may be configured to: simulate, based on a plurality of pumping pressures, fracturing processes corresponding to the plurality of pumping pressures through a finite element model, and determine fracturing effects corresponding to the plurality of pumping pressures;

determine a target pumping pressure based on the fracturing effects; and control, based on the target pumping pressure, the fracturing pump to inject a fracturing fluid into a fracture at the target pumping pressure.

The fracturing pump is a device or an apparatus used to inject a high-pressure fluid into a subterranean oil or gas formation to form a fracture. In some embodiments, the fracturing pump may be configured to pump a certain flow rate of the fracturing fluid. The fracturing fluid may be a mixture fluid of a base fluid (e.g., water, oil, gel, etc.), a thickener (e.g., hydroxypropyl guar gum, etc.), a proppant (e.g., sand, ceramic particles, etc.), and an additive (e.g., an anti-swelling agent, a bactericide, a gel breaker, etc.).

The pumping pressure refers to an injection pressure at which the fracturing fluid is pumped. In some embodiments, the pumping pressure may be obtained through a user input unit of an interactive interface.

The fracturing effect refers to a parameter used to measure an effect in enhancing an oil and gas well production and/or a degree in optimizing a fracture morphology of a fracturing operation. The larger the value of the fracturing effect, the better the effect in enhancing the oil and gas well production and/or the degree in optimizing the fracture morphology.

In some embodiments, the computing server may extract the oil and gas well production of an oil and gas well after fracturing, and a length of a primary fracture and a density of secondary fractures in a reservoir based on a result of the finite element model simulating a fracturing operation at a certain pumping pressure, so as to determine the fracturing effect. Merely by way of example, the fracturing effect may be determined by the following equation (1).

$$E = {k}_{1} \frac{{Q}_{2} - {Q}_{1}}{{Q}_{1}} + {k}_{2} L + {k}_{3} ρ \qquad ( 1 )$$

where E denotes the fracturing effect; Q₂ denotes the oil and gas well production of the oil and gas well after fracturing; Q₁ denotes an oil and gas well production before fracturing; L denotes the length of the primary fracture in the reservoir; ρ denotes the density of the secondary fractures in the reservoir; and k₁, k₂, and k₃ denote an oil and gas well production coefficient, a fracture length coefficient, and a fracture density coefficient, respectively.

In some embodiments, values of k₁, k₂, and k₃ may be correlated with a reservoir lithology and a permeability of the reservoir, and may be set by a person skilled in the art based on experience. The reservoir lithology refers to a homogeneity degree of a rock type (e.g., sandstone, shale, and carbonate) of the reservoir. The more homogeneous the reservoir lithology, the value of k₂ may be appropriately increased. The lower the permeability of the reservoir, the value of k₃ may be appropriately increased.

It is understood that the more homogeneous the reservoir lithology, the greater the impact of the primary fracture on the reservoir. A fracture with a longer length penetrates more rock layers, which significantly improves the conductivity of the reservoir. In a reservoir with a low permeability, the density of the secondary fractures is even more critical, and an increase in the density of the secondary fractures enhances the complexity of the fracture network, which improves the conductivity.

The target pumping pressure refers to a pumping pressure corresponding to a fracturing effect that satisfies a preset requirement. The preset requirement may be preset by a person skilled in the art. In some embodiments, the computing server may determine the fracturing effects corresponding to the plurality of pumping pressures in a manner described above, take a pumping pressure corresponding to a maximum fracturing effect as the target pumping pressure, and control the fracturing pump to inject the fracturing fluid into the fracture based the target pumping pressure.

In some embodiments of the present disclosure, in different reservoir environments, the influence of the expected production capacity of the oil and gas well after fracturing, the length of the primary fracture, and the density of the secondary fractures on the fracturing effect may vary depending on actual conditions of the reservoir. Therefore, the evaluation accuracy of the fracturing effect can be improved by comprehensive consideration of the geologic conditions of the reservoir.

In some embodiments, as shown in FIG. 5, the system may further include a first monitoring device. The first monitoring device may be configured to monitor a residual fracturing fluid pumped by the fracturing pump. The computing server may be further configured to: obtain the residual fracturing fluid based on the first monitoring device; in response to determining that the residual fracturing fluid is less than a first residual threshold, determine a pumping power of the fracturing pump based on the residual fracturing fluid, and control the fracturing pump to operate at the pumping power; the first residual threshold being determined by a trained large language model based on the plurality of pumping pressures and the finite element model.

The first monitoring device may be configured to monitor the residual fracturing fluid pumped by the fracturing pump. Merely by way of example, the first monitoring device may include a monitoring camera, a surveillance camera, a flow sensor, or the like.

The residual fracturing fluid refers to a residual amount of fracturing fluid that is not pumped. In some embodiments, the first monitoring device (e.g., the flow sensor) may be disposed at a fracturing fluid discharge port of the fracturing pump to monitor a flow rate of the fracturing fluid pumped by the fracturing pump in real time so as to determine the residual fracturing fluid.

The first residual threshold refers to a threshold at which an adjustment of the pumping power of the fracturing pump is triggered. In some embodiments, the trained large language model may give a recommendation based on the plurality of pumping pressures and the finite element model, and a person skilled in the art may determine the first residual threshold based on the recommendation.

In some embodiments, in response to determining that the residual fracturing fluid is less than the first residual threshold, the computing server may reduce the pumping power of the fracturing pump at a preset reduction magnitude based on a reduction degree of the residual fracturing fluid, and control the fracturing pump to operate at an adjusted pumping power. The preset reduction magnitude may be determined based on the reduction degree of the residual fracturing fluid through a first preset table. The first preset table may be constructed based on historical data. Each reduction degree of the residual fracturing fluid in the first preset table corresponds to one preset reduction magnitude. The greater the reduction degree of the residual fracturing fluid, the greater the preset reduction magnitude.

In some embodiments of the present disclosure, in response to determining that the residual fracturing fluid is insufficient, the computing server may reduce consumption of the fracturing fluid by reducing the pumping power of the fracturing pump, so as to obtain more time for replenishing the fracturing fluid, which prevents interruption of the fracturing operation due to the insufficient fracturing fluid.

In some embodiments, as shown in FIG. 5, the system may further include a second monitoring device, a raw material mixing device, and a raw material conveying device. The second monitoring device may be configured to monitor an amount of a raw material in the raw material mixing device. The computing server may be further configured to obtain the amount of the raw material based on the second monitoring device; in response to determining that the amount of the raw material is less than a second residual threshold, activate the raw material conveying device to convey at least one fracturing fluid raw material to the raw material mixing device; in response to determining that the amount of the raw material is not less than the second residual threshold, determine a mixing power of the raw material mixing device based on a current pumping power of the fracturing pump and control the raw material mixing device to mix, at the mixing power, the at least one fracturing fluid raw material in the raw material mixing device; the second residual threshold being determined by the trained large language model based on the current pumping pressure of the fracturing pump, the current pumping power, and the finite element model.

The second monitoring device may be configured to monitor the amount of the raw material in the raw material mixing device. Merely by way of example, the second monitoring device may include a monitoring camera, a surveillance camera, a flow sensor, or the like. The amount of the raw material refers to a residual amount of the at least one fracturing fluid raw material in the raw material mixing device. The at least one fracturing fluid raw material may include a base fluid (e.g., water, oil, gel, etc.), a thickener (e.g., hydroxypropyl guar gum, etc.), a proppant (e.g., sand, ceramic particles, etc.), an additive (e.g., an anti-swelling agent, a bactericide, a gel breaker, etc.), etc.

The raw material mixing device may be configured to mix the at least one fracturing fluid raw material. For example, the raw material mixing device may include a mixer, etc. The raw material conveying device may be configured to convey the at least one fracturing fluid raw material to the raw material mixing device. For example, the raw material conveying device may include a conveyor belt, a conveying pipeline, etc. In some embodiments, the raw material conveying device may be coupled or connected with the raw material mixing device to convey the at least one fracturing fluid raw material to the raw material mixing device.

In some embodiments, the second monitoring device (e.g., the surveillance camera) may be disposed above the raw material mixing device, so as to obtain the amount of the raw material in the raw material mixing device in real time.

The second residual threshold refers to a threshold at which replenishment and mixing of the fracturing fluid raw material are triggered. In some embodiments, the large language model may give a recommendation based on a current pumping pressure and the current pumping power of the fracturing pump, and the finite element model, and a person skilled in the art may determine the second residual threshold based on the recommendation. In some embodiments, the current pumping pressure and the current pumping power may be obtained through the user input unit of the interactive interface.

In some embodiments, in response to determining that the amount of the raw material is less than the second residual threshold, the computing server may immediately activate the raw material conveying device to convey the at least one fracturing fluid raw material to the raw material mixing device.

In some embodiments, in response to determining that the amount of the raw material is not less than the second residual threshold, the computing server may determine the mixing power of the raw material mixing device based on the current pumping power of the fracturing pump through a second preset table. The second preset table may be constructed based on historical data. Each pumping power of the fracturing pump in the second preset table corresponds to one mixing power of the raw material mixing device. For example, the higher the pumping power of the fracturing pump, the higher the mixing power of the raw material mixing device.

In some embodiments of the present disclosure, the computing server can replenish the fracturing fluid raw material in time when the amount of the raw material is insufficient, and determine the mixing power of the raw material mixing device based on the pumping power of the fracturing pump when the amount of the raw material is sufficient, which prevents interruption of the fracturing operation due to the insufficient fracturing fluid, thereby guaranteeing the continuity and efficiency of the fracturing operation.

Some embodiments of the present disclosure further provide a finite element modeling method for hydraulic fracturing problems based on a large language model (hereinafter referred to as the “method”). The method may be implemented by the system.

In some embodiments, the hydraulic fracturing problems may include a fracture propagation mechanism, proppant selection, induced earthquake, wellbore damage, fracturing fluid optimization, pressure control, three-dimensional fracturing network evolution, micro-seismic interpretation, fracturing effect evaluation and flowback. One of the problems is denoted by X, and a training process of the large language model for a problem X includes: A, data preparation: A-1, data collection: selecting diverse data sources as external data to ensure that a data volume is large enough; A-2, data cleansing: removing information irrelevant to the problem X and removing duplicates; B. data preprocessing: B-1, formatting: converting document and text forms into a uniform format readable by the large language model; B-2, building a glossary: the glossary containing all keywords in the problem X as far as possible; C. training model and configuration settings: C-1, model architecture: selecting a training model, wherein an existing pre-trained model is used as a basis to reduce training time and resources; C-2, setting hyperparameters: determining a learning rate and a batch size, and setting a count of valid trainings; D. model training: D-1, training objective: the objective being to generate a database and a key parameter file in the form of “keyword-data value” in the problem X; wherein the database contains all the keywords and related data values of the problem X; the key parameter file contains a sub-problem name, a geometric keyword, an attribute keyword, and a mesh keyword; D-2, evaluation adjustment: evaluating a training result and adjusting an incorrect training result until a correct key parameter file is generated; E. model deployment: E-1, platform selection: a deployment platform being a cloud service platform; E-2, API interface: selecting the API interface to support real-time reasoning.

In some embodiments, the training process of the large language model for the problem X further includes: B-3, word frequency filtering: grouping some words expressing the same meaning into a same keyword to reduce the size of the glossary.

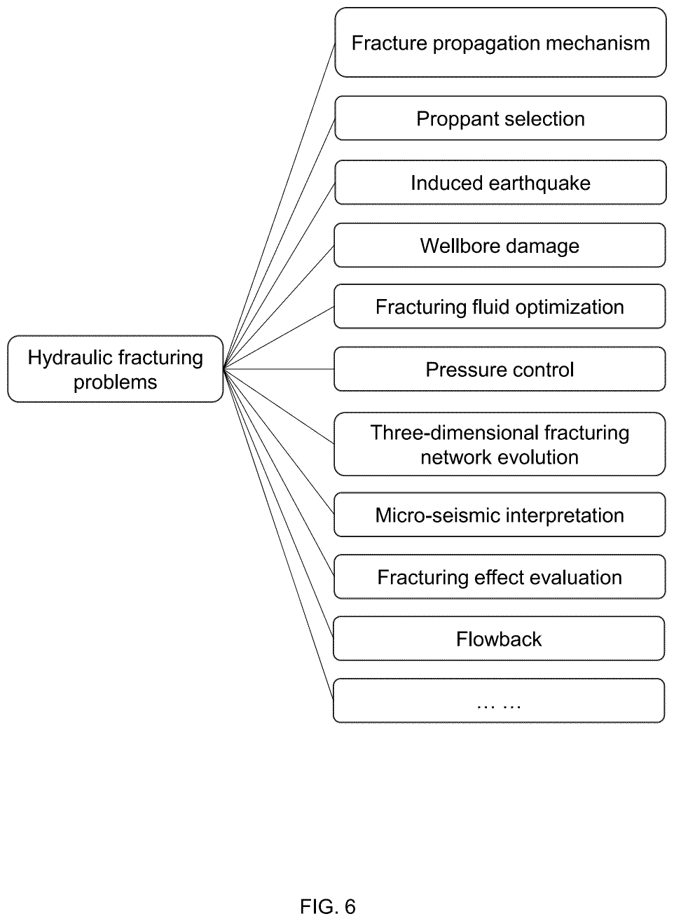

FIG. 6 is a block diagram illustrating categorization of sub-problems of hydraulic fracturing problems according to some embodiments of the present disclosure. As shown in FIG. 6, the hydraulic fracturing problems may include a plurality of sub-problems such as a fracture propagation mechanism, proppant selection, induced earthquake, wellbore damage, fracturing fluid optimization, pressure control, three-dimensional fracturing network evolution, micro-seismic interpretation, fracturing effect evaluation and flowback, etc., X representing one of the plurality of the sub-problems. A sub-problem database may be constructed based on the categorization of the sub-problems by a person skilled in the art.

In some embodiments, one of the sub-problems corresponds to one large language model. Merely by way of example, as shown in FIG. 6, when X represents the “fracture propagation mechanism”, the training process of the large language model includes the following operations.

### A, Data Preparation.

A-1, data collection: selecting diverse data sources as external data, such as a web crawler, an open dataset, a digital book, etc., to ensure that the data volume is large enough, wherein the external data is a content relevant to the “fracture propagation mechanism”.

Meanwhile, a manual input content needs to be an input content of a first input terminal to train the large language model capable of generating the key parameter file.

A-2, data cleansing: removing information irrelevant to the “fracture propagation mechanism” and removing duplicates.

### B, Data Preprocessing.

B-1, formatting: converting the document and text forms into the uniform format readable by the large language model.

B-2, building the glossary: the glossary containing keywords (e.g., a geometric keyword, a material property keyword, an initial condition keyword, a boundary condition keyword, etc.) of the “fracture propagation mechanism”.

B-3, word frequency filtering: grouping some words expressing the same meaning into the same keyword to reduce the size of the glossary. For example, “an intersection angle” and “a proximity angle” are grouped into the “an intersection angle”.

### C, Training Model and Configuration Settings.

C-1, model architecture: selecting an appropriate training model, wherein an existing pre-trained model is used as a basis to reduce training time and resources,

C-2, setting hyperparameters: determining a learning rate and a batch size, and setting a count of valid trainings. More descriptions regarding determining the learning rate may be found in the present disclosure below.

### D, Model Training.

D-1, training objective: the objective being to generate a database and a key parameter file in the form of “keyword-data value” in the problem “fracture propagation mechanism”; wherein the database contains all the keywords and related data values of the problem “fracture propagation mechanism”; the key parameter file contains a sub-problem name, a geometric keyword, an attribute keyword, and a mesh keyword, etc.

D-2, evaluation adjustment: manually evaluating a training result, and adjusting an incorrect training result until a correct key parameter file is generated.

### E, Model Deployment.

E-1, platform selection: a deployment platform being a cloud service platform.

E-2, API interface: selecting an appropriate API interface to support real-time reasoning.

The key parameter file in the embodiment includes a key parameter describing a physical model, which is illustrated here as an example of the problem “fracture propagation mechanism”.

Merely by way of example, the manual input content may include: constructing a two-dimensional model of linear elastic fracture mechanics (LEFM), a length being 100 m, a width being 50 m, an initial fracture shape being a rectangle, a position being on a left side, an elasticity modulus of a material being 1.5 GPa, a Poisson's ratio being 0.18, and a formation pressure being 9.81 MPa, wherein a fracture criterion based on a stress intensity factor is adopted.

The key parameter file may be refined based on the database, including the sub-problem name, the geometric keyword, the attribute keyword, the mesh keyword, etc.

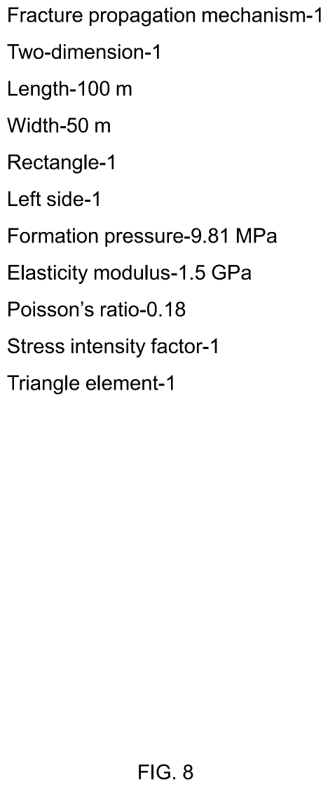

FIG. 8 is a schematic diagram illustrating a key parameter file according to some embodiments of the present disclosure. As shown in FIG. 8, the key parameter file obtained based on the manual input content described above may include:
a sub-problem name: “fracture propagation mechanism-1”;
a geometric keyword: “two-dimension-1”, “length-100 m”, “width-50 m”, “rectangle-1”, and “left side-1”;
an attribute keyword: “formation pressure-9.81 MPa”, “elasticity modulus-1.5 GPa”, “Poisson's ratio-0.18”, and “stress intensity factor-1”;
a mesh keyword: “triangle element-1”, etc.

After the above operations, the database of the sub-problem “fracture propagation mechanism” is obtained, and the training process of the large language model is completed. When the user input unit input a content, a generation result is the key parameter file. Databases and large language models corresponding to other sub-problems of the hydraulic fracturing problems may also be created and trained by the process.

In some embodiments, determining a learning rate may include: obtaining a glossary; determining a data feature based on the glossary; and determining the learning rate based on the data feature.

The data feature refers to a feature related to the keyword. For example, the data feature may include the keyword in the glossary and a word frequency corresponding to the keyword. The word frequency refers to a ratio of a count of occurrence of one keyword to a total count of keywords containing the problem X in the glossary. In some embodiments, the system may perform statistics on the count of occurrence of the one keyword in the glossary, and determine the ratio of the count of occurrence of the one keyword to the total count of the keywords containing the problem X in the glossary, so as to obtain the data feature.

In some embodiments, the system may determine a learning rate by determining a variation coefficient of word frequencies corresponding to the keywords in the glossary based on the data feature of the glossary.

The variation coefficient is used to describe a concentration degree of the importance of the keywords. The higher the variation coefficient, the greater the difference in importance among the keywords, which indicates that semantics is concentrated. Merely by way of example, the variation coefficient may be a ratio of a standard deviation of the word frequencies of the keywords to a mean value of the word frequencies of the keywords in the glossary.

In some embodiments, when model parameters are updated based on a sample t at a kth iteration, a learning rate nₜ^{k} is correlated with a current iteration k and the sample t. The smaller the current iteration k, the higher the variation coefficient corresponding to the sample t, and the larger the learning rate nₜ^{k}.

In some embodiments, a parameter mesh coupling tool may generate the finite element model file by coupling the key parameter file with a mesh file, the finite element model file including a control statement, a node, a unit definition, an initial value, a boundary condition, a material definition, a working condition, a time step size, etc.

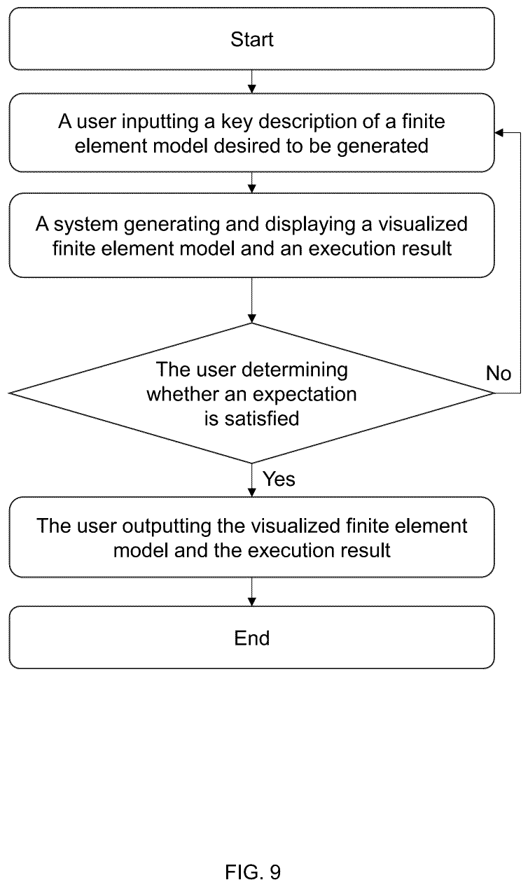

FIG. 9 is a flowchart illustrating an exemplary process of a user modeling by using a finite element modeling system for hydraulic fracturing problems based on a large language model according to some embodiments of the present disclosure. As shown in FIG. 9, the user may perform finite element modeling of the hydraulic fracturing problems using the system, including the following operations.

S1, a user may input a key description of a finite element model desired to be generated into a user input unit, an API interface being consistent with an API interface of a trained large language model.

S2, the large language model of a cloud service platform may generate a key parameter file by processing the description input by the user; a mesh tool may generate a mesh file by reading the key parameter file; and a parameter mesh coupling tool may generate a finite element model file by processing the key parameter file and the mesh file.

A computing server may execute the finite element model file. The finite element model and an execution result may be presented using a visualization unit. A system output unit may prompt the user of completion of modeling and execution, and a display interface may display a visualized finite element model and the execution result.

S3, the user may determine whether an expectation is satisfied; in response to determining that the user expectation is not satisfied, the user needs to re-input the description; in response to determining that the user expectation is satisfied, the user is capable of choosing to output the finite element model and the execution result.

In some embodiments, the system may further determine a first description accuracy based on the key description; in response to determining that the first description accuracy is less than a preset threshold, determine a prompt instruction and prompt the user through the display interface; obtain a supplemental key description through an interactive interface; determine an updated key description based on the key description and the supplemental key description; determine a second description accuracy based on the updated key description; in response to determining that the second description accuracy is not less than the preset threshold, generate an updated key parameter file based on the updated key description; and generate an updated mesh file by reading the updated key parameter file by the mesh tool; and generate the finite element model file by processing the updated key parameter file and the updated mesh file by the parameter mesh coupling tool.

The first description accuracy refers to a parameter for measuring a description accuracy of the key description. In some embodiments, the system may determine an information entropy of the key description based on the key description, and take a reciprocal of the information entropy as the first description accuracy of the key description.

In some embodiments, the preset threshold may be correlated with a model type of a simulation experiment, and the model type of the simulation experiment may be determined based on the key description.

In some embodiments, the large language model may extract the model type of the simulation experiment from the key description. Merely by way of example, if the key description is: constructing a two-dimensional model of LEFM, a length being 100 m, a width being 50 m, an initial fracture shape being a rectangle, a position being on a left side, an elasticity modulus of a material being 1.5 GPa, a Poisson's ratio being 0.18, a formation pressure being 9.81 MPa, and a fracture criterion based on a stress intensity factor being adopted, the large language model may determine that the model type of the simulation experiment is the two-dimensional model of LEFM.

In some embodiments, in response to determining that the large language model may extract the model type of the simulation experiment from the key description, the system may determine a difficulty of the simulation experiment based on the model type of the simulation experiment by querying a preset experiment difficulty table. The greater the difficulty of the simulation experiment, the greater the preset threshold. The preset experiment difficulty table may be set by a person skilled in the art based on experience.

It is understood that the greater the difficulty of the experimental model, and the more detail the finite element model is required to provide, the preset threshold should be appropriately increased, where an increase magnitude may be determined by a person skilled in the art based on experience.

In some embodiments, in response to determining that the large language model cannot extract the model type of the simulation experiment from the key description, the model type of the simulation experiment is null, and the system may set the preset threshold to a theoretical maximum. The theoretical maximum may be determined by a person skilled in the art based on experience.

The prompt instruction is an instruction used by the system to prompt the user to supplement the supplemental key description. In some embodiments, in response to the first description accuracy is less than the preset threshold, the system may generate the prompt instruction based on a preset program. The preset program may be preset by a person skilled in the art.

The supplemental key description is a description related to finite element modeling that is supplemented by the user. In some embodiments, the supplemental key description may be input by the user through the interactive interface.

The updated key description is a description obtained by merging the key description and the supplemental key description. In some embodiments, the system may obtain the updated key description by integrating the key description and the supplemental key description based on the key description and the supplemental key description.

The second description accuracy refers to a parameter for measuring a description accuracy of the updated key description. In some embodiments, the system may determine an information entropy of the updated key description based on the updated key description, and take a reciprocal of the information entropy as the second description accuracy of the updated key description.

In some embodiments, in response to determining that the second description accuracy is greater than or equal to the preset threshold, the system may generate the updated key parameter file based on the updated key description by processing the updated key description using the large language model. It is understood that in response to determining that the second description accuracy is less than the preset threshold, the system may generate the prompt instruction again to prompt the user to input a second supplemental key description, obtain a second updated key description based on the updated key description and the second supplemental key description, and determine a third description accuracy. If the third description accuracy is greater than or equal to the preset threshold, the key parameter file may be generated. If the third description accuracy is less than the preset threshold, the above process may be repeated until a description accuracy output at a last iteration is greater than or equal to the preset threshold, and the key parameter file may be generated.

In some embodiments of this disclosure, constructing the finite element model is a complex and time-consuming process. By evaluating the key description of the finite element model and making the supplement and/or the adjustment when needed, the failure rate in constructing the finite element model can be reduced while reducing the construction cost.

In some embodiments, the system may obtain a feedback description of the user through the interactive interface; determine a model adjustment parameter by performing large language model analysis on the feedback description; and adjust the finite element model file based on the model adjustment parameter, the model adjustment parameter including a modeling accuracy. The adjusting the finite element model file based on the model adjustment parameter may include: generating the finite element model based on the modeling accuracy. More descriptions regarding the finite element model file may be found in the present disclosure above.

The feedback description refers to description information that the user feeds back for a generated finite element model. It is understood that the content of the key description is a requirement for the functionality of the finite element model, while the feedback description is the evaluation (e.g., the finite element modeling is slow, a computational accuracy is low, the computational result of the model is unstable, etc.) of the finite element model. In some embodiments, the feedback description may be input by the user through the interactive interface.

The model adjustment parameter refers to a parameter related to adjusting the finite element model. For example, the model adjustment parameter may include the modeling accuracy, a boundary condition for modeling, an optimization material for the finite element model, a fracture shape and position calibration, a loading condition, etc. In some embodiments, each modeling session corresponds to one model adjustment parameter.

In some embodiments, taking the user needing to adjust the modeling accuracy as an example, the user also needs to input a current modeling accuracy and an expected modeling accuracy of the finite element model in the feedback description. The system may determine a mesh density and a mesh type (e.g., a two-dimensional triangle and quadrangle, a three-dimensional tetrahedron and hexahedron, etc.) of the finite element model based on the expected modeling accuracy, and generate a final finite element model.

In some embodiments of the present disclosure, when the finite element model is constructed, an error may occur between the key description input by the user and an expectation, and different modeling adjustment parameters may have an impact on the subsequent modeling result. Accordingly, when the finite element model does not satisfy the user expectation, the modeling adjustment parameter can be quickly adjusted through the feedback of the user so as to satisfy the requirements of the user.

It should be noted that the foregoing description of the process is intended to be exemplary and illustrative only and does not limit the scope of application of the present disclosure. For a person skilled in the art, various corrections and changes to the process can be made under the guidance of the present disclosure. However, the corrections and changes remain within the scope of the present disclosure.

For each patent, patent application, patent application publication, or other materials cited in the present disclosure, such as articles, books, specifications, publications, documents, or the like, the entire contents of which are hereby incorporated into the present disclosure as a reference. The application history documents that are inconsistent or conflict with the content of the present disclosure are excluded, and the documents that restrict the broadest scope of the claims of the present disclosure (currently or later attached to the present disclosure) are also excluded. It should be noted that if there is any inconsistency or conflict between the description, definition, and/or use of terms in the auxiliary materials of the present disclosure and the content of the present disclosure, the description, definition, and/or use of terms in the present disclosure is subject to the present disclosure.

Finally, it should be understood that the embodiments described in the present disclosure are only used to illustrate the principles of the embodiments of the present disclosure. Other variations may also fall within the scope of the present disclosure. Therefore, as an example and not a limitation, alternative configurations of the embodiments of the present disclosure may be regarded as consistent with the teaching of the present disclosure. Accordingly, the embodiments of the present disclosure are not limited to the embodiments introduced and described in the present disclosure explicitly.

What is claimed is:

1. A finite element modeling system for hydraulic fracturing problems based on a large language model, comprising a client, a cloud service platform, and a computing server, wherein
the client consists of an interactive interface and a display interface, the interactive interface including a user input unit and a system output unit, and the display interface serving as a window of the system for displaying a visualized finite element model and an execution result;
the cloud service platform includes a storage space, a first input terminal, a second input terminal, a third input terminal, a transmission terminal, a trained large language model, a mesh tool, and a parameter mesh coupling tool; wherein
the first input terminal is an input port configured to receive an external data input and a user input and input the external data input and the user input to the large language model;
the second input is an input port configured to receive a key parameter file and input the key parameter file to the mesh tool;
the third input is an input port configured to receive the key parameter file and a mesh file and input the key parameter file and the mesh file to the parameter mesh coupling tool;
the transmission terminal is a transmission port configured to transmit a finite element model file from the storage space of the cloud service platform to a storage unit of the computing server;
the trained large language model is a large language model configured to generate the key parameter file based on a user input content;
the mesh tool is a tool configured to generate the mesh file based on the key parameter file being invoked by the cloud service platform;
the parameter mesh coupling tool is a tool configured to generate the finite element model file based on the key parameter file and the mesh file being invoked by the cloud service platform;
the computing server includes the storage unit, an operation unit, and a visualization unit.

2. The finite element modeling system of claim 1, wherein
the user input unit is a window where a user inputs a content in a composite form of texts, pictures, and vector graphics;
the system output unit is a window where the system displays a prompt to the user.

3. The finite element modeling system of claim 1, wherein the storage space is a space configured to store a database and the key parameter file generated by the trained large language model, the mesh file generated by the mesh tool, and the finite element model file generated by the parameter mesh coupling tool.

4. The finite element modeling system of claim 3, wherein the database stores all data occurring during a training process of the large language model in the form of “keyword-data value”;
the key parameter file is a result generated by the trained large language model processing the user input content, and a parameter file in the key parameter file is in the form of “keyword-data value”;
the mesh file is generated by the cloud service platform invoking the mesh tool based on the key parameter file;
the finite element model file is generated by the parameter mesh coupling tool coupling the key parameter file with the mesh file, the finite element model file being capable of being executed directly by the operation unit to generate a result.

5. The finite element modeling system of claim 1, wherein the storage unit is a unit configured to store the finite element model file;
the operation unit is a unit configured to execute the finite element model file;
the visualization unit is a unit configured to visualize the finite element model and the execution result.

6. The finite element modeling system of claim 1, further comprising a fracturing pump, wherein the computing server is configured to:
simulate, based on a plurality of pumping pressures, fracturing processes corresponding to the plurality of pumping pressures through the finite element model, and determine fracturing effects corresponding to the plurality of pumping pressures;
determine a target pumping pressure based on the fracturing effects; and
control, based on the target pumping pressure, the fracturing pump to inject a fracturing fluid into a fracture at the target pumping pressure.

7. The finite element modeling system of claim 6, further comprising a first monitoring device, wherein the first monitoring device is configured to monitor a residual fracturing fluid pumped by the fracturing pump;
the computing server is further configured to:
obtain the residual fracturing fluid based on the first monitoring device;
in response to determining that the residual fracturing fluid is less than a first residual threshold, determine a pumping power of the fracturing pump based on the residual fracturing fluid, and control the fracturing pump to operate at the pumping power; the first residual threshold being determined by the trained large language model based on the plurality of pumping pressures and the finite element model.

8. The finite element modeling system of claim 7, further comprising a second monitoring device, a raw material mixing device, and a raw material conveying device, wherein the second monitoring device is configured to monitor an amount of a raw material in the raw material mixing device;
the computing server is further configured to:
obtain the amount of the raw material based on the second monitoring device;
in response to determining that the amount of the raw material is less than a second residual threshold, activate the raw material conveying device to convey at least one fracturing fluid raw material to the raw material mixing device;
in response to determining that the amount of the raw material is not less than the second residual threshold, determine a mixing power of the raw material mixing device based on a current pumping power of the fracturing pump and control the raw material mixing device to mix, at the mixing power, the at least one fracturing fluid raw material in the raw material mixing device; the second residual threshold being determined by the trained large language model based on the current pumping pressure of the fracturing pump, the current pumping power, and the finite element model.

9. A finite element modeling method for hydraulic fracturing problems based on a large language model, implementing the finite element modeling system of claim 1, comprising:
a user inputting a key description of a finite element model desired to be generated into a user input unit, an API interface being consistent with an API interface of a trained large language model;
the large language model of a cloud service platform generating a key parameter file by processing the description input by the user; a mesh tool generating a mesh file by reading the key parameter file; and a parameter mesh coupling tool generating a finite element model file by processing the key parameter file and the mesh file;
a computing server executing the finite element model file, the finite element model and an execution result being presented using a visualization unit, a system output unit prompting the user of completion of modeling and execution, and a display interface displaying a visualized finite element model and the execution result;
the user determines whether an expectation is satisfied; in response to determining that the user expectation is not satisfied, the user needing to re-input the description; in response to determining that the user expectation is satisfied, the user is capable of choosing to output the finite element model and the execution result.

10. The finite element modeling method of claim 9, wherein the hydraulic fracturing problems include a fracture propagation mechanism, proppant selection, induced earthquake, wellbore damage, fracturing fluid optimization, pressure control, three-dimensional fracturing network evolution, micro-seismic interpretation, fracturing effect evaluation and flowback, one of the problems is denoted by X, and a training process of the large language model for a problem X includes:
A. data preparation:
A-1, data collection: selecting diverse data sources as external data to ensure that a data volume is large enough;
A-2, data cleansing: removing information irrelevant to the problem X and removing duplicates;
B. data preprocessing:
B-1, formatting: converting document and text forms into a uniform format readable by the large language model;
B-2, building a glossary: the glossary containing all keywords in the problem X as far as possible;
C. training model and configuration settings:
C-1, model architecture: selecting a training model, wherein an existing pre-trained model is used as a basis to reduce training time and resources;
C-2, setting hyperparameters: determining a learning rate and a batch size, and setting a count of valid trainings;
D. model training:
D-1, training objective: the objective being to generate a database and a key parameter file in the form of “keyword-data value” in the problem X; wherein the database contains all the keywords and related data values of the problem X; the key parameter file contains a sub-problem name, a geometric keyword, an attribute keyword, and a mesh keyword;
D-2, evaluation adjustment: evaluating a training result and adjusting an incorrect training result until a correct key parameter file is generated;
E. model deployment:
E-1, platform selection: a deployment platform being the cloud service platform;
E-2, API interface: selecting the API interface to support real-time reasoning.

11. The finite element modeling method of claim 10, further comprising:
B-3, word frequency filtering: grouping some words expressing a same meaning into a same keyword to reduce a size of the glossary.

12. The finite element modeling method of claim 10, wherein the determining a learning rate includes:
obtaining the glossary;
determining a data feature based on the glossary; and
determining the learning rate based on the data feature.

13. The finite element modeling method of claim 10, wherein the parameter mesh coupling tool generates the finite element model file by coupling the key parameter file with the mesh file, the finite element model file including a control statement, a node, a unit definition, an initial value, a boundary condition, a material definition, a working condition, and a time step size.

14. The finite element modeling method of claim 9, further comprising:
determining a first description accuracy based on a key description;
in response to determining that the first description accuracy is less than a preset threshold, determining a prompt instruction and prompting the user through the display interface;
obtaining a supplemental key description through the interactive interface;
determining an updated key description based on the key description and the supplemental key description;
determining a second description accuracy based on the updated key description;
in response to determining that the second description accuracy is not less than the preset threshold, generating an updated key parameter file based on the updated key description; and
generating an updated mesh file by reading the updated key parameter file by the mesh tool; and generating the finite element model file by processing the updated key parameter file and the updated mesh file by the parameter mesh coupling tool.

15. The finite element modeling method of claim 9, further comprising:
obtaining a feedback description of the user through the interactive interface;
determining a model adjustment parameter by performing large language model analysis on the feedback description; and
adjusting the finite element model file based on the model adjustment parameter, the model adjustment parameter including a modeling accuracy; wherein
the adjusting the finite element model file based on the model adjustment parameter includes:
generating the finite element model based on the modeling accuracy.
